(19) United States
(12) Patent Application Publication
(10) Pub. No.: US 2014/0042825 A1
(43) Pub. Date: Feb. 13, 2014

(54) SWITCH FOR GENERATING LONG PULSE VOLTAGE AND APPARATUS FOR GENERATING LONG PULSE CURRENT

(71) Applicants: Joon Hyuck Kwon, Daejeon (KR); Eung Jo Kim, Daejeon (KR); Jae Bok Lee, Gimhae-si (KR); Sug Hun Chang, Busan (KR)

(72) Inventors: Joon Hyuck Kwon, Daejeon (KR); Eung Jo Kim, Daejeon (KR); Jae Bok Lee, Gimhae-si (KR); Sug Hun Chang, Busan (KR)

(73) Assignee: Agency for Defense Development, Daejeon (KR)

(21) Appl. No.: 13/988,933

(22) PCT Filed: Nov. 25, 2011
(86) PCT No.: PCT/KR11/09053

§ 371 Date: May 22, 2013

(30) Foreign Application Priority Data
Apr. 8, 2011 (KR) 10-2011-0032606

(51) Int. Cl. H03K 3/02

(52) U.S. Cl. CPC H03K 3/02
USPC 307/106

(57) ABSTRACT

The long pulse voltage generating switch according to the present invention comprises a switch control unit for generating a control signal that gradually increases a frequency in a front section of a wave height of a long pulse waveform desired to be simulated and gradually decreases the gradually increased frequency in an end section; and a switch turned on and off by the generated control signal and having a constant turn-on time period while the switch is turned on and off. Therefore, a reference voltage waveform of a long pulse waveform to be simulated can be easily generated, and a long pulse current can be easily generated using the reference voltage waveform.

### TECHNICAL FIELD

The present invention relates to a long pulse voltage generating switch and a long pulse current generating apparatus, and more specifically, to a switch for generating a long pulse voltage waveform through gradual increase and decrease of a frequency and an apparatus for generating a long pulse current using the long pulse voltage generating switch.

### BACKGROUND ART

With the advancement in electronic communication technologies, electronic, communication, and control devices are getting miniaturized and integrated further more and come to be an indispensable element in modern life. Damages or malfunctions of such digital devices may introduce tremendous direct or indirect national losses, as well as inconveniences in real life in a knowledge-based society. Impulses generated by natural phenomena such as a thunderbolt and the like and electromagnetic waves that can be generated by artificial manipulations such as a nuclear explosion and the like may lead to an error in such electronic devices. The electromagnetic waves generated by an impulse are a factor critical to precise electronic devices, and thus measures for protecting the precise electronic devices from the electromagnetic waves are required. However, in order to study the protection measures, characteristics of elements for protecting the electronic devices from the electromagnetic impulses need to be analyzed, and studies on large-scale impulse generation apparatuses capable of generating test impulses should be preceded.

An impulse current generator is generally configured with a series circuit of a capacitor C, a resistor R, and an inductor L and generates an impulse current waveform by discharging electrical charges charged in the capacitor through the resistor R and the inductor L. Here, excessive vibration waveforms, damped vibration waveforms, and non-vibration waveforms are generated depending on the relation among the values of R, L, and C.

A long pulse current waveform among the impulse current waveforms has an extremely long damping time as long as about tens of seconds compared with a rapid rising time. In a convention method, a circuit having an extremely large RC time constant is needed in order to generate a long pulse current waveform. To this end, a capacitor of an extremely large capacity is required, and equipment of an extremely vast scale is needed considering withstanding voltage of the capacitor.

In another method, the wave front portion is shaped using an RLC series circuit as a damped vibration condition, and the wave tail portion can be configured with an RL series circuit so that current may be exponentially damped depending on a time constant of L/R. This is a method for generating a waveform by operating a discharge switch until an initial vibration waveform generated by the RLC series circuit arrives at the maximum point, i.e., an initial peak value (¼ cycle), and then driving an additional discharge switch at the time point of the peak value so that electrical charges can be discharged through the RL circuit. In this case, there needs two discharge switches synchronized with each other, i.e., a discharge switch for discharging the capacitor and a discharge switch for discharging inductor energy, and a high-precision trigger apparatus is needed to synchronize the two switches with each other. In this case, each of the RLC elements is expected to be very large in size, and it is inconvenient in that the inductor should be adjusted depending on impedance of the circuit of a product to be tested.

### DISCLOSURE OF INVENTION

### Technical Problem

Therefore, the present invention has been made in view of the above problems, and it is an object of the present invention to provide a switch for generating a long pulse voltage waveform through gradual increase and decrease of a frequency and an apparatus for generating a long pulse current using the long pulse voltage generating switch.

Technical problems to be solved in the present invention are not limited to the technical problems described above, and unmentioned other technical problems will become apparent to those skilled in the art from the following descriptions.

### Solution to Problem

To accomplish the above object, according to one aspect of the present invention, there is provided a long pulse voltage generating switch comprising: a switch control unit for generating a control signal that gradually increases a frequency in a front section of a wave height of a long pulse waveform desired to be simulated and gradually decreases the gradually increased frequency in an end section; and a switch turned on and off by the generated control signal and having a constant turn-on time period while the switch is turned on and off.

At this point, the end section may include a section reaching as far as 50% of the wave height.

Here, if a time period between a time point where the frequency starts to be applied and a time point corresponding to 50% of the wave height is T_{E}, an end point of the end section may be within a range of 4×T_{E}.

In addition, the control signal may be a signal for maintaining the turn-on time period of the switch to be constant.

In addition, the switch may include an IGBT.

According to another aspect of the present invention, there is provided a long pulse current generating apparatus comprising: a power source for supplying a predetermined voltage; a long pulse voltage generating switch connected to the power source, turned on and off by a control signal that gradually increases a frequency in a front section of a wave height of a long pulse waveform desired to be simulated and gradually decreases the gradually increased frequency in an end section, and having a constant turn-on time period while the switch is turned on and off; a pulse shaping unit for generating a long pulse voltage waveform depending on the on-and-off of the long pulse voltage generating switch; a resistor for converting the generated long pulse voltage waveform into a long pulse current waveform; and a free wheeling diode connected between the long pulse voltage generating switch and the pulse shaping unit in parallel.

At this point, the pulse shaping unit may include: an inductor connected between the long pulse voltage generating switch and the resistor in series and a capacitor connected between the inductor and the resistor in parallel.

Here, the inductor L and the capacitor C_{L} may satisfy mathematical expressions shown below.

$$L = \frac{D ( 1 - D ) {V}_{in}}{f Δ {i}_{L}} , \\ {C}_{L} \approx \frac{100}{2 π f {R}_{L}} ≫ \frac{1}{2 π f {R}_{L}}$$

Here,

$$D = \frac{{τ}_{u}}{T} ,$$

Vᵢₙ is voltage of the power source, τᵤ is a turn-on time period of the long pulse voltage generating switch, f is a frequency of the control signal, Δi_{I} is a ripple of output current of the long pulse voltage generating switch, and R_{L} is a resistance value of the resistor.

In addition, voltage Vₒᵤₜ supplied to the resistor may be defined as a mathematical expression shown below.

Vₒᵤₜ=Vᵢₙ t_{uf}

Here, Vᵢₙ is voltage of the power source, τᵤ is a turn-on time period of the long pulse voltage generating switch, and f is a frequency of the control signal.

In addition, a minimum frequency fₘᵢₙ of the control signal may satisfy mathematical expression shown below.

$$\frac{1}{{f}_{min}} = {T}_{max} ≪ {t}_{r} ≪ {t}_{FWHM}$$

Here, tᵣ is a wave front length, and t_{FWHM} is a wave tail length.

### Advantageous Effects of Invention

The long pulse voltage generating switch of the present invention is turned on and off depending on a gradually increased and decreased frequency, and thus a waveform of a long pulse current to be simulated can be implemented in a corresponding voltage waveform.

The long pulse current generating apparatus can be easily designed and implemented using the long pulse voltage generating switch.

The long pulse current generating apparatus implemented as described above can easily generate a desired long pulse current by adjusting a frequency of a control signal which controls the long pulse voltage generating switch, in stead of installing a large-scale capacitor.

### BRIEF DESCRIPTION OF DRAWINGS

FIG. 1 is a block diagram showing a long pulse voltage generating switch of the present invention

FIG. 2 is a view schematically showing an example of a long pulse waveform desired to be simulated.

FIG. 3 is a view schematically showing an example of a control signal.

FIG. 4 is a block diagram showing a long pulse current generating apparatus of the present invention.

FIG. 5 is a circuit diagram showing a long pulse current generating apparatus of the present invention.

FIG. 6 is a view schematically showing current flow when a switch is turned on and off in a long pulse current generating apparatus of the present invention.

FIG. 7 is a circuit diagram showing an example of a switch control unit in a long pulse voltage generating switch of the present invention.

FIG. 8 is a circuit diagram showing a switch-side optic link electrically connected to a switch among optic links.

FIG. 9 is a graph showing a waveform related to a V/F conversion circuit.

FIG. 10 is a view schematically showing a control signal for maintaining a turn-on time period of a switch to be constant regardless of changes in a frequency.

FIG. 11 is a view schematically showing voltage ripples of an inductor included in a waveform shaping circuit.

FIG. 12 is a graph showing examples of output waveforms of a long pulse current apparatus.

### MODE FOR THE INVENTION

A long pulse voltage generating switch and a long pulse current generating apparatus of the present invention will be hereafter described in detail, with reference to the accompanying drawings.

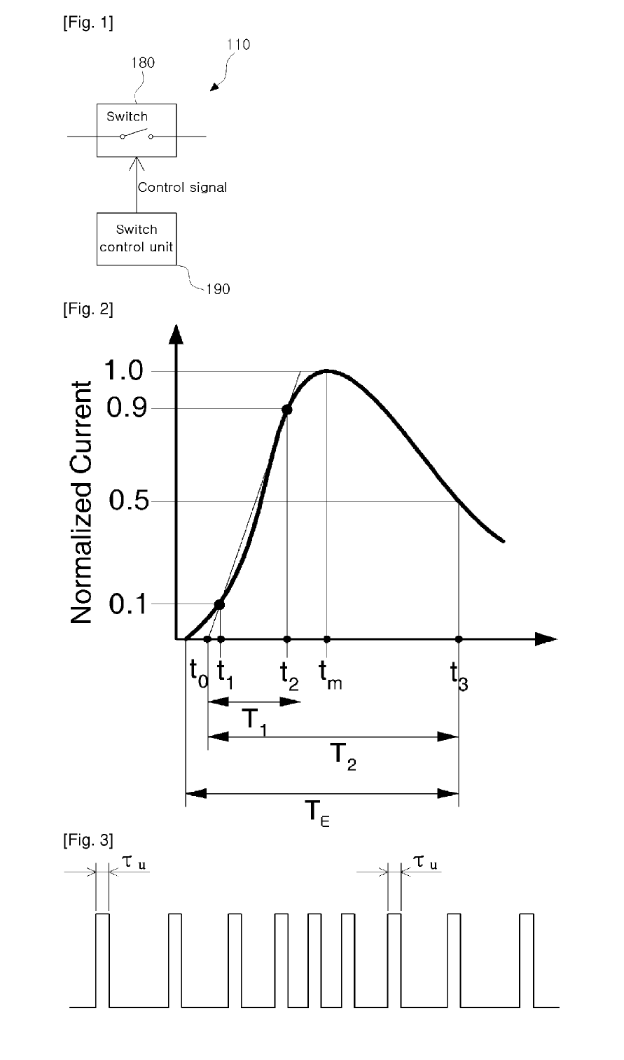

FIG. 1 is a block diagram showing a long pulse voltage generating switch of the present invention

The long pulse voltage generating switch shown in FIG. 1 includes a switch control unit 190 for generating a control signal that gradually increases a frequency in a front section of a wave height of a long pulse waveform desired to be simulated and gradually decreases the gradually increased frequency in an end section and a switch 180 turned on and off by the generated control signal and having a constant turn-on time period while the switch is turned on and off.

The switch control unit 190 generates a control signal for turning on and off the switch 180. The control signal generated at this time has a gradually increasing or decreasing frequency. At this point, increase or decrease of the frequency relates to a long pulse waveform, i.e., a long pulse current waveform, to be simulated.

The long pulse current waveform is a kind of impulse current waveform, and the impulse current waveform can be expressed as shown in FIG. 2. The impulse current waveform may show an irregular shape at every moment, and FIG. 2 shows a normalized impulse current waveform.

A point of 10% of the wave height is connected to a point of 90% of the wave height using a straight line, and a time period T₁ from an intersection of the straight line and a point of 0% of the current to an intersection of the straight line and a point of 100% of the current is referred to as a wave front length. The wave front length corresponds to 1.25 times of the rising time Tᵣ expressed as a difference between a time point T₁ at 10% of the maximum value and a time point t₂ at 90% of the maximum value. In addition, a difference between a time point t₃ at 50% of the wave height and the virtual origin point t0 is referred to as a wave tail length T2, and the impulse current waveform is generally expressed as ‘wave front length T₁/wave tail length T2’. Accordingly, the long pulse current waveform also can be expressed as ‘wave-front-length/wave-tail-length’.

Although it is described to generate a long pulse current waveform having a maximum current value of 1,000 A, a wave front length of 0.2 seconds, and a wave tail length of 25 seconds in the present invention as an example, the values used in the example are not limited thereto.

The switch control unit 190 generates a control signal that gradually increases the frequency in the front section of a wave height of a long pulse waveform and gradually decreases the gradually increased frequency in the end section so that the long pulse voltage generating switch shown in FIG. 1 may generate a long pulse voltage waveform related to a long pulse current waveform expressed as wave-front-length/wave-tail-length.

At this point, the wave crest can be included in the front or end section.

The end section may include a section reaching as far as 50% of the wave height. Since the long pulse current waveform is expressed as ‘wave-front-length/wave-tail-length’, a long pulse is meaningful only when the end section includes a section reaching as far as at least the wave tail length. Here, if a time period between a time point where the frequency starts to be applied and a time point corresponding to 50% of the wave height is T_{E}, the end point of the end section can be within a range of 4×T_{E}.

The reason why the end point of the end section is so far is to include a characteristic of a long damping time because of the characteristics of the long pulse current waveform.

The switch 180 is turned on and off by the control signal generated by the switch control unit 190. As the frequency of the control signal increases, the number of turning on and off is increased, and as the frequency of the control signal decreases, the number of turning on and off is decreased. Accordingly, if the number of turning on and off is increased, the number of turning on is also increased, and thus output voltage is increased, whereas if the number of turning on and off is decreased, the number of turning on is also decreased, and thus the output voltage is decreased. At this point, it is notable that the turn-on time period varies. That is, if the frequency increases, the number of turning on is increased, whereas the time period staying in the turned-on state is decreased. Contrarily, if the frequency decreases, the number of turning on is decreased, whereas the time period staying in the turned-on state is increased. Accordingly, in order to reliably control the output voltage using the frequency, the time period τᵤ staying in the turned-on state should be constant regardless of changes in the frequency. To this end, the switch may include a means for maintaining the turn-on time period (a duration of time staying in the turned-on state) to be constant.

Alternatively, the switch control unit may generate a control signal for maintaining the turn-on time period τᵤ of the switch to be constant. For example, if the switch is configured to be turned on in a high level of the control signal, the switch control unit may generate a control signal that allows all high level sections to have a constant time period and provide the switch with the control signal.

Whichever configuration it may be used, if the turn-on time period τᵤ is constant, the switch may control the output voltage by adjusting the frequency.

The switch at this point may include an insulated gate bipolar transistor (IGBT) applicable to high-speed switching.

If the long pulse voltage generating switch described above is used, a long pulse voltage waveform, i.e., the basis of a long pulse current waveform to be simulated, can be generated. If the long pulse voltage waveform is used, a variety of long pulse current waveforms can be easily generated using a capacitor, an inductor, and a resistor having a low capacity, compared with conventional methods.

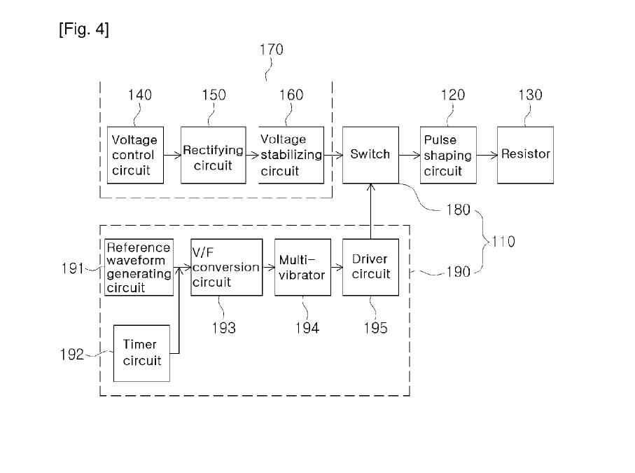

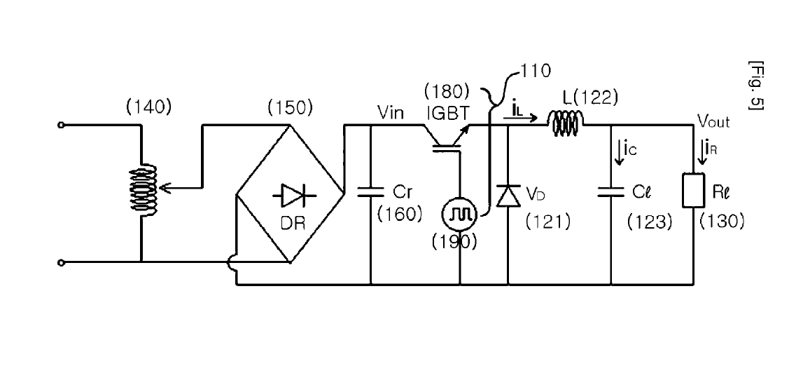

FIG. 4 is a block diagram showing a long pulse current generating apparatus of the present invention, which includes the long pulse voltage generating switch 110 shown in FIG. 1.

The long pulse current generating apparatus shown in FIG. 4 includes a power source 170 for supplying a predetermined voltage, a long pulse voltage generating switch 110 connected to the power source, turned on and off by a control signal that gradually increases a frequency in a front section of a wave height of a long pulse waveform desired to be simulated and gradually decreases the gradually increased frequency in an end section, and having a constant turn-on time period while the switch is turned on and off, a pulse shaping unit 120 for generating a long pulse voltage waveform depending on the on-and-off of the long pulse voltage generating switch, a resistor 130 for converting the generated long pulse voltage waveform into a long pulse current waveform, and a free wheeling diode connected between the long pulse voltage generating switch and the pulse shaping unit in parallel.

The power source 170 is a device for supplying a constant voltage, i.e. a direct current voltage.

The power source may include, for example, a voltage control circuit 140, a rectifying circuit 150, and a voltage stabilizing circuit 160.

The voltage control circuit 140 is supplied with commercial AC power (60 Hz, 220V/single phase or 380V/3 wires) and controls magnitude of output voltage using a slide-AC or other methods. In addition, the power source may include a boosting circuit provided with a high voltage transformer for obtaining high voltage power.

The rectifying circuit 150 converts AC voltage into DC voltage to charge the AC voltage in the capacitor and may have a configuration of combining a plurality of diodes in series and parallel considering withstanding voltage and current capacity of the diodes used for the rectifying circuit.

The voltage stabilizing circuit 160 can be configured as a capacitor bank for flattening the voltage and is preferably configured to have a large capacity possible in order to reduce a ripple factor according to changes in the input voltage.

The long pulse voltage generating switch 110 includes a switch 180 and a switch control unit 190. The switch 180 may be, for example, a high-speed IGBT capable of performing an on-off operation depending on a high frequency signal having a cycle of 1 to 10 kHz. The IGBT is a semiconductor element for high power switching, which can stably operate at high-voltage high-current compared with other elements such as an FET and the like. The on-off operation of the switch 180 depends on a control signal generated by the switch control unit 190.

The pulse shaping circuit 120 is configured as a combination of an inductor and a capacitor and generates an output waveform depending on the on-off operation of the switch.

The resistor 130 is an element that finally obtains a long pulse current waveform and may be, for example, 5 ohms.

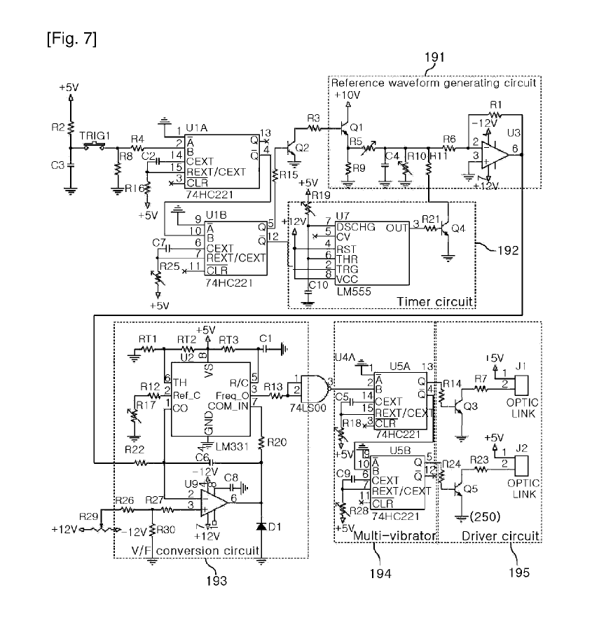

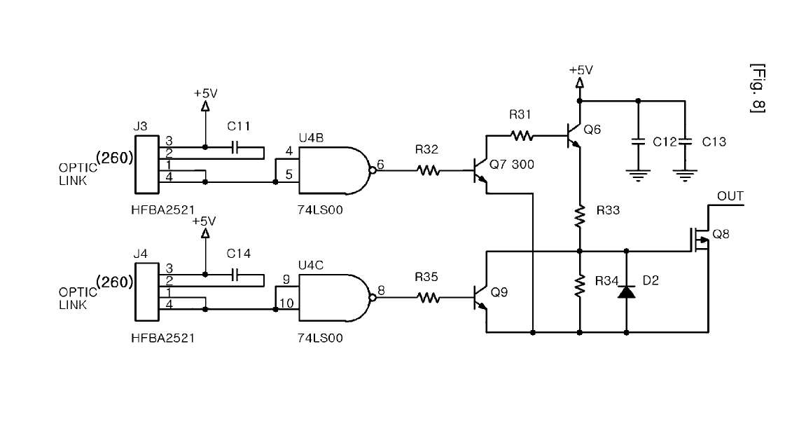

The switch control unit 190 may be configured as a TTL logic circuit for suppressing affects of electrical noises that can be generated in a high-voltage high-current environment. The switch control unit may include, for example, a reference waveform generating circuit 191, a timer circuit 192, a voltage-to-frequency (V/F) conversion unit 193, a multi-vibrator 194, and a driver circuit 195, as shown in FIG. 7.

The reference waveform generating circuit 191 is an element for generating a reference waveform having a time parameter that is the same as the time parameter of a long pulse current waveform outputted from the resistor and may be configured with, for example, a capacitor, a discharge resistor, an FET switch, and an inverting amplifier, as shown in FIG. 7.

The timer circuit 192 is configured using an LM555 IC and the like in order to limit the operation time of the switch configured with an IGBT and the like.

The V/F conversion circuit 193 converts voltage into a frequency using a V/F conversion IC, e.g., LM331, and an operational (OP) amplifier.

At this point, the relation between the input voltage Vᵢₙ and the output frequency fout is as shown in mathematical expression 1.

$${f}_{out} = \frac{- {V}_{IN}}{2.09 V} \cdot \frac{{R}_{s}}{{R}_{IN}} \cdot \frac{1}{{R}_{t} {C}_{t}} \qquad [ Mathematical expression 1 ]$$

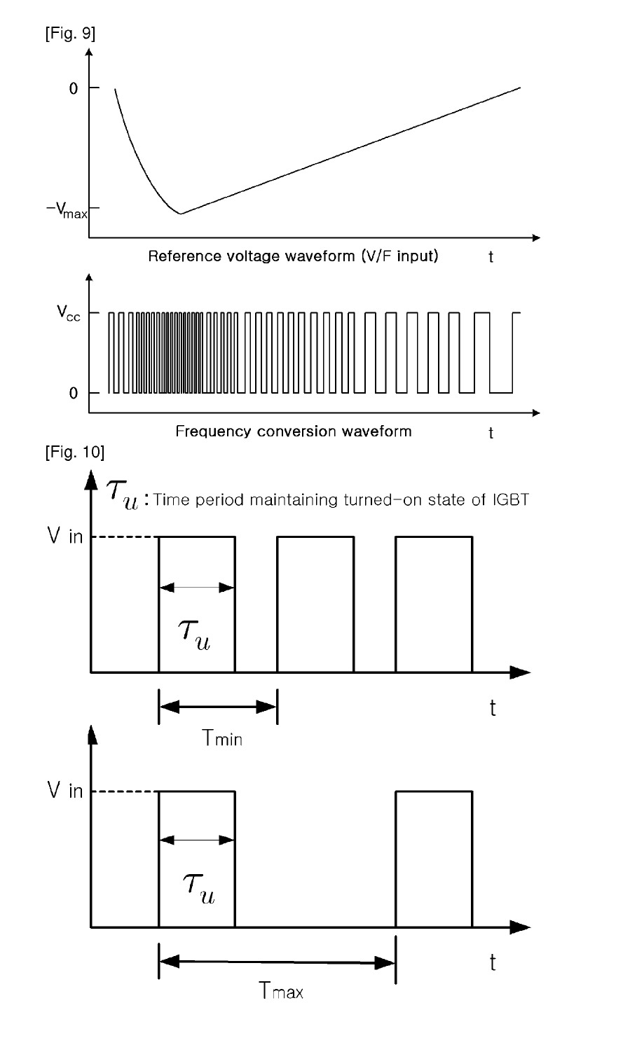

FIG. 9 is a graph showing a waveform related to a V/F conversion circuit, and as the voltage of a voltage waveform generated by the reference waveform generating unit increases, the frequency is increased, and as the voltage decreases, the frequency is decreased.

The multi-vibrator circuit 194 is an element for receiving the V/F converted signal and generating a driver output signal for driving the switch and may include a multi-vibrator IC, e.g., 74HC221. The multi-vibrator circuit controls a switch operation time by adjusting the resistor R and the capacitor C connected outside of the IC so that the turn-on time τᵤ of the switch can be maintained to be constant regardless of changes in the input frequency. Accordingly, the turn-on time varying depending on the changes in the frequency as shown in FIG. 9 will be constant to have a turn-on time period of τᵤ as shown in FIG. 3.

The driver circuit 195 is an element for driving the switch and uses FET switches for reliable operation.

On the other hand, optic links are additionally installed at the output terminal of the driver circuit and the switch, and thus stability can be secured by electrically separating the switch control unit from the switch.

FIG. 8 is a circuit diagram showing a switch-side optic link electrically connected to a switch among optic links. Observing the figure, it is understood that a pulse signal is supplied to the switch using a transistor switched by a signal inputted through the optic link.

FIG. 5 is a circuit diagram showing a long pulse current generating apparatus of the present invention.

The circuit diagram of a long pulse current generating apparatus shown FIG. 5 is an example of implementing the block diagram shown in FIG. 4.

A transformer is disposed as the voltage control circuit 140, and a bridge diode DR is disposed as the rectifying circuit 150, and in addition, a capacitor Cr is disposed as the voltage stabilizing circuit 160.

An IGBT (an npn type) is disposed as the switch 180, and specifically, the drain is connected to the output terminal of the bridge diode, and the gate is connected to the switch control unit 190. The switch and the switch control unit configure the long pulse voltage generating switch 110.

The pulse shaping unit 120 includes an inductor L 122 connected between the IGBT 180 corresponding to the long pulse voltage generating switch 110, specifically, the switch 180, and a resistor R_{L}(Rₗ) 130 in series, and a capacitor C_{L}(Cₗ) 123 connected between the inductor L 122 and the resistor R_{I}, 130 in parallel.

The free wheeling diode V_{D} 121 is connected in parallel in a direction connecting the negative terminal between the source terminal of the IGBT and the inductor L.

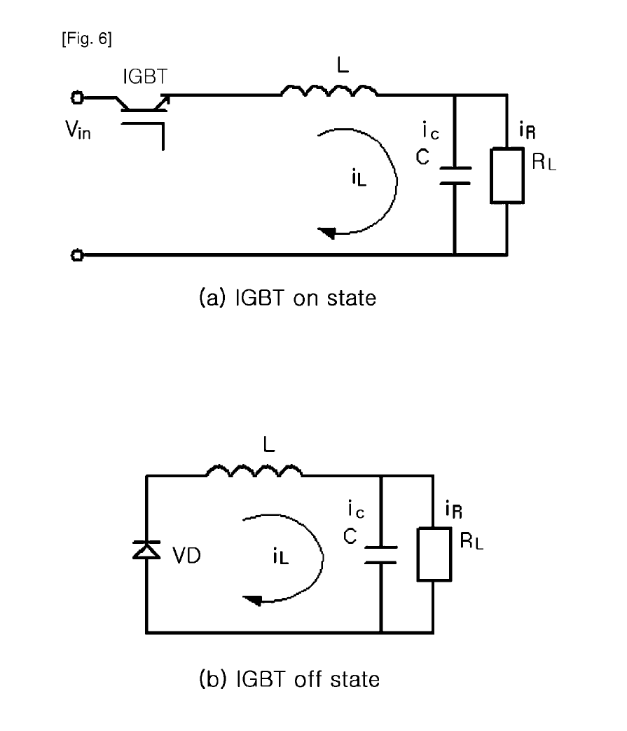

Current flow in the circuit is described with reference to FIG. 6.

If the IGBT is turned on, energy is charged in the inductor L as soon as the current flows to the resistor R_{L}, through the inductor L. Next, if the IGBT is turned off, the energy charged in the inductor L is discharged to the output side through the free wheeling diode V_{D}.

If it is assumed that the operating cycle of the IGBT is T as shown in FIG. 10 and the switch is turned on only for a time period of τᵤ, output voltage Vₒᵤₜ supplied to the resistor R_{L} is expressed as shown in mathematical expression 2.

$${V}_{out} = \frac{1}{T} {\int }_{0}^{T} {V}_{in} ( t ) d t = \frac{{V}_{in}}{T} {τ}_{u} \qquad [ Mathematical expression 2 ]$$

At this point, if

$$D = \frac{{τ}_{u}}{T} ,$$

mathematical expression 2 can be expressed as mathematical expression 3.

Vₒᵤₜ=DVᵢₙ =Vᵢₙ t_{uf} [Mathematical expression 3]

Here, Vᵢₙ is voltage of the power source, τᵤ is a turn-on time period of the long pulse voltage generating switch, and f is a frequency of the control signal.

Accordingly, it is understood that if turn-on time τᵤ of the IGBT is constant, the output voltage Vₒᵤₜ varies depending on the switching frequency of the IGBT. Since the turn-on time τᵤ is maintained to be constant by the configuration of the switch and the switch control unit as described above, a desired voltage waveform can be obtained by adjusting only the switching frequency. The switching frequency of the IGBT is the frequency of the control signal generated and supplied by the switch control unit.

According to mathematical expression 3, if the switching frequency f is increased, the output voltage is increased, and if the switching frequency is decreased, the output voltage is decreased.

Through the characteristics shown in mathematical expression 3 and the configuration maintaining the turn-on time period r to be constant, the long pulse current generating apparatus controls the output waveform depending on variation of the frequency of the switch, in which the reference waveform generating unit previously generates a small signal reference waveform desired to be generated, and the V/F conversion circuit converts the reference waveform into a frequency signal. The switching frequency is high in the steep rising edge, and the frequency decreases slowly in the gentle falling edge. Since the switch operates depending on the frequency signal varying as described above, a long pulse voltage of a desired form is generated, and if the long pulse voltage is discharged through a low resistance load, a long pulse current can be obtained.

In order to suppress ripples of the output waveform and obtain a correct waveform, the minimum frequency fₘᵢₙ of the control signal should satisfy the mathematical expression shown below.

$$\frac{1}{{f}_{min}} = {T}_{max} ≪ {t}_{r} ≪ {t}_{FWHM} \qquad [ Mathematical expression 4 ]$$

Here, tᵣ is a wave front length, and t_{FWHM} is a wave tail length.

For example, the wave front length may be 0.2 sec, and the wave tail length may be 25 sec.

In order to maintain a stable switching operation within a range satisfying the condition of mathematical expression 4, a switching cycle can be varied within a range defined below.

Maximum cycle: Tₘₐₓ=1 ms, fₘᵢₙ=1 kHz

Minimum cycle: Tₘᵢₙ=100 μs, fmax=10 kHz

In addition, a duty ratio is set to 0.9 in the maximum switching frequency in order to obtain a maximum output current, and at this time, the turn-on time period τᵤ can be fixed to 90 μs. Since the turn-on time period τᵤ is a constant value that has noting to do with changes in the switching frequency, output voltage can be varied within a range shown below by mathematical expression 3.

$${V}_{outmin} = \frac{90 μ s}{1000 μ s} {V}_{in} = 0.09 {V}_{in}$$

$${V}_{outmax} = \frac{90 μ s}{100 μ s} {V}_{in} = 0.9 {V}_{in}$$

The inductor L can be designed as shown below.

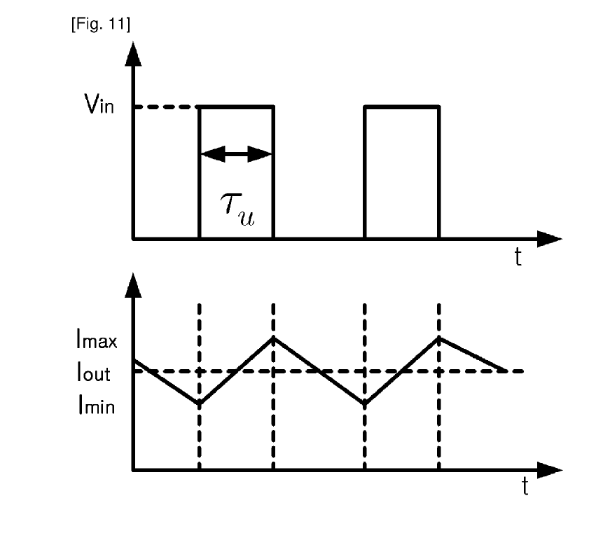

Voltage of the inductor in FIG. 11 is as shown in mathematical expression 5.

$$L \frac{d {i}_{L}}{d t} = {V}_{in} - {V}_{out} \qquad [ Mathematical expression 5 ]$$

Here, if it is assumed that the switching frequency is sufficiently high, mathematical expression 5 can be assumed as mathematical expression 6.

$$L \frac{d {i}_{L}}{d t} = {V}_{in} - {V}_{out} ≃ L \frac{Δ {i}_{L}}{DT} \qquad [ Mathematical expression 6 ]$$

ΔΔᵢ_{_{L}}in mathematical expression 6 is as shown in mathematical expression 7.

$$\begin{matrix}Δ {i}_{L} = \frac{1}{L} ( {V}_{in} - {V}_{out} ) {τ}_{u} \\ = \frac{{V}_{in}}{L} ( 1 - \frac{{V}_{out}}{{V}_{in}} ) {τ}_{u} \cdot \frac{T}{T} \\ = \frac{{V}_{in}}{L} ( 1 - D ) DT \\ = \frac{{V}_{{i}^{′} n}}{L} D ( 1 - D ) \cdot \frac{1}{f} \\ = D ( 1 - D ) \frac{{V}_{in}}{fL}\end{matrix} \qquad [ Mathematical expression 7 ]$$

If mathematical expression 7 is rewritten in terms of L, it is as shown in expression 8.

$$L = \frac{D ( 1 - D ) {V}_{in}}{f Δ {i}_{L}} \qquad [ Mathematical expression 8 ]$$

Here,

$$D = \frac{{τ}_{u}}{T} ,$$

Vᵢₙ is the voltage of the power source, τᵤ is a turn-on time period of the long pulse voltage generating switch, f is a frequency of the control signal, and Δi_{L} is a ripple of output current of the long pulse voltage generating switch.

The ripple Δi_{L} shown in FIG. 11 has a relation expressed in mathematical expression 9.

Δi_{L}=iₘₐₓ−iₘᵢₙ

iₘₐₓ=iₒᵤₜ−0.5Δi_{L} [Mathematical expression 9]

Capacitor C_{L} is a filter for suppressing high frequency ripples of the output voltage, and it can be designed to satisfy mathematical expression 10.

$${C}_{L} \approx \frac{100}{2 π {fR}_{L}} ≫ \frac{1}{2 π {fR}_{L}} \qquad [ Mathematical expression 10 ]$$

Here, f is a frequency of the control signal, and R_{L} is a resistance value of the resistor.

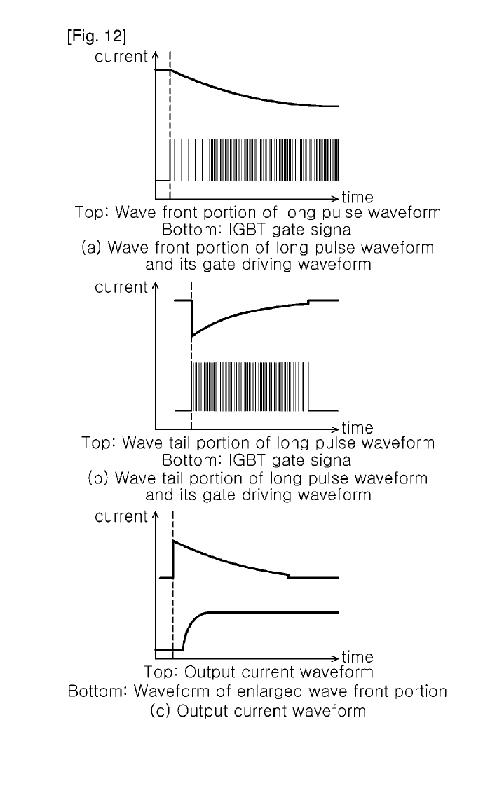

FIG. 12 shows examples of output waveforms of a long pulse current generating apparatus configured based on the circuit diagrams disclosed in FIGS. 5, 7, and 8. FIG. 12(a) shows a wave front portion of a long pulse waveform and an IGBT control signal at the point, and FIG. 12(b) shows a wave tail portion and an IGBT control signal at the point. FIG. 12(c) shows the entire current waveform and an enlarged wave front portion, and it is confirmed that a long pulse current has been generated.

According to the configurations described above, a long pulse current generating apparatus is configured using a switching element and can be used to analyze and simulate characteristics of electrical and electronic devices and protecting apparatuses for protecting the electrical and electronic devices from electromagnetic waves that can be generated by thunderbolts, surges, or the like. Therefore, it is possible to construct a system that is more economical and reliable than conventional long pulse current generating apparatuses.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

### INDUSTRIAL APPLICABILITY

The present invention can be applied to an apparatus for generating a long pulse current.

Particularly, the present invention can be used for a system that performs a test and evaluates performance related to Electromagnetic pulse (EMP) of protecting devices, including electrical and electronic devices, to meet the situation of an age demanding high-quality power.

1. A long pulse voltage generating switch comprising:
a switch control unit for generating a control signal that gradually increases a frequency in a front section of a wave height of a long pulse waveform desired to be simulated and gradually decreases the gradually increased frequency in an end section; and
a switch turned on and off by the generated control signal and having a constant turn-on time period while the switch is turned on and off.

2. The switch according to claim 1, wherein the end section includes a section reaching as far as 50% of the wave height.

3. The switch according to claim 2, wherein if a time period between a time point where the frequency starts to be applied and a time point corresponding to 50% of the wave height is T_{E}, an end point of the end section is within a range of 4×T_{E}.

4. The switch according to claim 1, wherein the control signal is a signal for maintaining the turn-on time period of the switch to be constant.

5. The switch according to claim 1, wherein the switch includes an IGBT.

6. A long pulse current generating apparatus comprising:
a power source for supplying a predetermined voltage;
a long pulse voltage generating switch connected to the power source, for being turned on and off by a control signal that gradually increases a frequency in a front section of a wave height of a long pulse waveform desired to be simulated and gradually decreases the gradually increased frequency in an end section, and having a constant turn-on time period while the switch is turned on and off;
a pulse shaping unit for generating a long pulse voltage waveform depending on the on-and-off of the long pulse voltage generating switch;
a resistor for converting the generated long pulse voltage waveform into a long pulse current waveform; and
a free wheeling diode connected between the long pulse voltage generating switch and the pulse shaping unit in parallel.

7. The apparatus according to claim 6, wherein the pulse shaping unit includes:
an inductor connected between the long pulse voltage generating switch and the resistor in series; and
a capacitor connected between the inductor and the resistor in parallel.

8. The apparatus according to claim 7, wherein the inductor L and the capacitor C_{L} satisfy mathematical expressions shown below
$$L = \frac{D ( 1 - D ) {V}_{in}}{f Δ {i}_{L}}$$
$${C}_{L} \approx \frac{100}{2 π {fR}_{L}} ≫ \frac{1}{2 π {fR}_{L}}$$
where
$$D = \frac{{τ}_{u}}{T} ,$$
Vᵢₙ is voltage of the power source, τᵤ is a turn-on time period of the long pulse voltage generating switch, f is a frequency of the control signal, Δi_{L} is a ripple of output current of the long pulse voltage generating switch, and R_{L} is a resistance value of the resistor.

9. The apparatus according to claim 6, wherein voltage Vₒᵤₜ supplied to the resistor is defined as a mathematical expression shown below
Γₒᵤₜ=Γᵢₙτᵤf
where Vᵢₙ is voltage of the power source, τᵤ is a turn-on time period of the long pulse voltage generating switch, and f is a frequency of the control signal.

10. The apparatus according to claim 6, wherein a minimum frequency fₘᵢₙ of the control signal satisfies a mathematical expression shown below
$$\frac{1}{{f}_{min}} = {T}_{max} ≪ {t}_{r} ≪ {t}_{FWHM} ,$$
where tᵣ is a wave front length, and t_{FWHM} is a wave tail length.
